(19) United States
(12) Patent Application Publication
(10) Pub. No.: US 2012/0025750 A1
(43) Pub. Date: Feb. 2, 2012

(54) Portable Solar Power System

(76) Inventor: Philip F. Margo, Beverly Hills, CA (US)

(21) Appl. No.: 12/844,519

(22) Filed: Jul. 27, 2010

(51) Int. Cl. H01M 10/46; H01L 31/045

(52) U.S. Cl. 320/101; 136/245

(57) ABSTRACT

A portable solar power system, comprises a plurality of photovoltaic solar panels; storage batteries for storing energy generated by the photovoltaic solar panels; a charger operably connected to the photovoltaic solar panels for charging the storage batteries; a plurality of inverters operably connected to the respective photovoltaic solar panels for generating an AC output for connection to an outlet for feeding into an electric grid; and a switching circuit for automatically disconnecting the photovoltaic solar panels from the inverters and connecting the photovoltaic solar panels to the charger when power in the electric grid is down.

### FIELD OF THE INVENTION

The present invention relates generally to a photovoltaic solar power system and in particular to a portable photovoltaic solar power systems that can be plugged into a standard house outlet for feeding back into the electric grid and powering the electrical loads connected to the outlet circuit.

### BACKGROUND OF THE INVENTION

There is very little an individual can do to provide their own power. Wind-power incorporates huge windmills that cannot be placed in the great majority of homes and businesses. Other systems such as geothermal and wave technology are still not feasible for residential use. What is left is solar. The sun shines every day and provides huge amounts of power. However, except for installing a full solar array or just using low wattage units to provide energy for low-power electronic devices, there are hardly any products on the market that can make a serious dent in the average usage of electric power.

Current solar energy systems are expensive, must be installed by professionals and current solar panels are cumbersome and have limited efficiency. Though there are solar panels made in many different ways, there is none in the market that can be connected to any home electrical outlet and deliver sufficient current (500-1000 watts) that would serve to run the electric meter backwards. This would result in “banking” electricity for home and/or commercial use.

### SUMMARY OF THE INVENTION

The present invention provides a portable solar power system, comprising a plurality of photovoltaic solar panels; storage batteries for storing energy generated by the photovoltaic solar panels; a charger operably connected to the photovoltaic solar panels for charging the storage batteries; a plurality of inverters operably connected to respective the photovoltaic solar panels for generating an AC output for connection to an outlet for feeding into an electric grid; and a switching circuit for automatically disconnecting the photovoltaic solar panels from the inverters and connecting the photovoltaic solar panels to the charger when power in the electric grid is down.

### BRIEF DESCRIPTION OF THE DRAWINGS

FIG. 1 is a perspective view of an embodiment of a solar power system embodying the present invention.

FIG. 2 is a perspective view of a removable hinge used in the embodiment of FIG. 1.

FIG. 3 is a perspective view of the embodiment of FIG. 1, showing one panel in the upright position for stowage.

FIG. 4 is a perspective view of a bracket used to hold the panel in FIG. 3 in the upright position in cooperation with a removable member.

FIG. 5 is a perspective view of a bracket used to removably attach a member to support the panel of FIG. 3 in the upright position.

FIG. 6 is perspective view of a weatherproof electrical box containing a number of power outlets and a mode switch.

FIG. 7 is a schematic wiring diagram of the system of FIG. 1.

FIG. 8 is a perspective view of another embodiment of the system of FIG. 1.

### DETAILED DESCRIPTION OF THE INVENTION

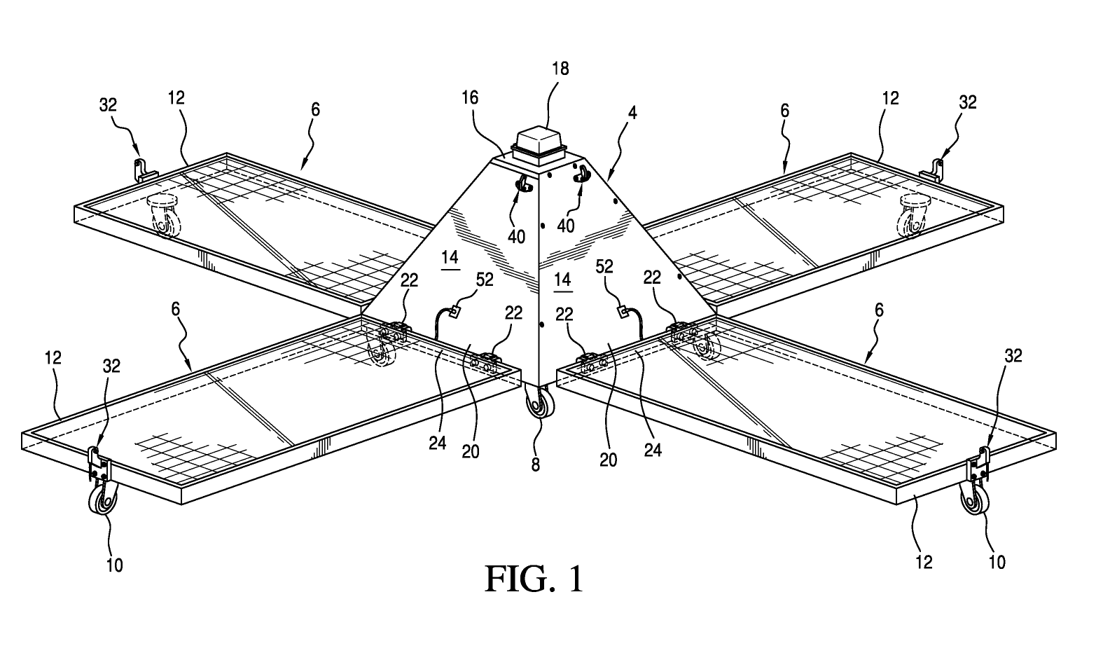

A solar power system 2 embodying the present invention is disclosed in FIG. 1. The system 2 includes a housing 4 and photovoltaic solar panels 6 hingedly and removably attached to the housing 2. A plurality of wheels 8 are disposed on the underside of the housing 2 to provide mobility and portability. Each panel 6 is also provided with a wheel 10 to provide support to the outer end 12 of the panel 6 when it is deployed in the horizontal position to directly expose the photovoltaic surfaces to the solar radiation. The wheels 8 and 10 allow the entire system 2 to be moved around with ease. Although the panels 6 are disclosed as rectangular, the shapes and sizes of the panels can vary depending on the need and the existing technology. The panels 6 are readily available from several sources, such as Andalay Solar, Inc., www.andalaysolar.com, Model No. ST175-1, which are 175 W each.

The housing 4 is preferably a truncated pyramid with a square base, a flat top and four sides. The pyramidal shape is advantageous in reducing shadow on the panels 6. The top portion 16 of the housing 4 provides an attachment base for a weatherproof box 18 for power outlets and switch, as will be described below. The panels 6 are preferably attached to the respective bottom portions 20 of the sides 14.

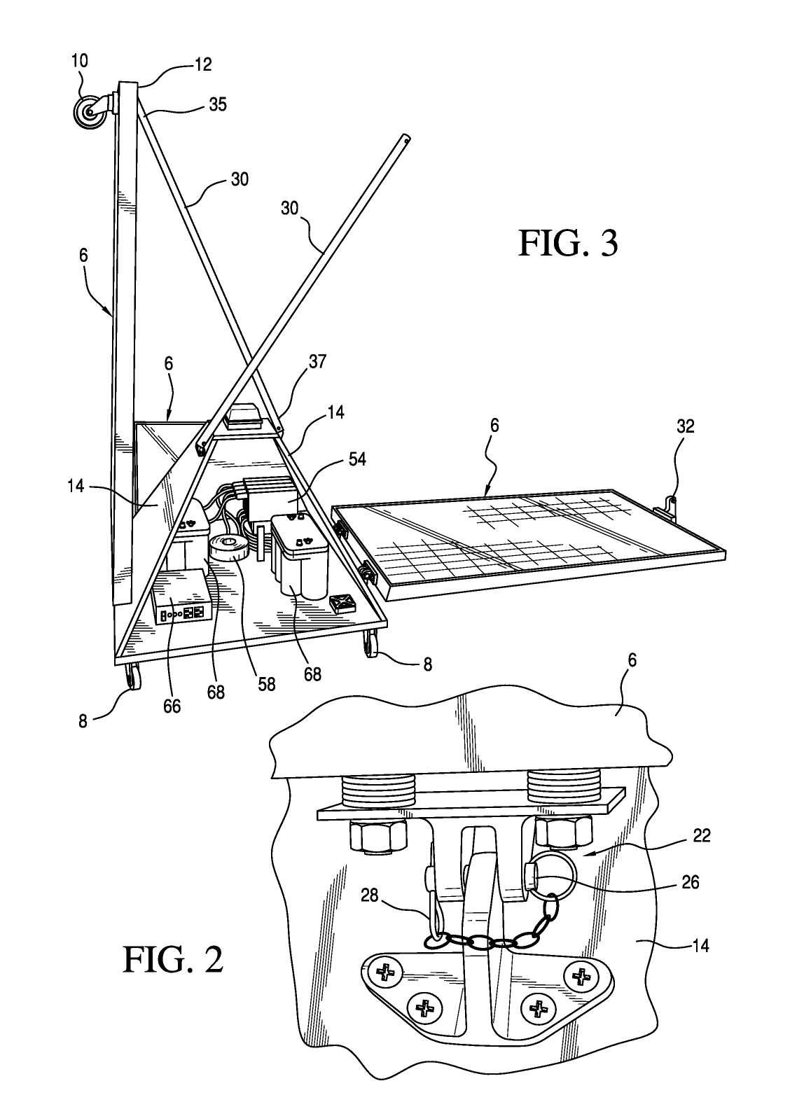

Referring to FIG. 2, hinges 22 are used to attach the near ends 24 of the panels 6 to the respective sides 14 of the housing 4. A removable pin 26, secured by a removable cotter pin 28, advantageously allows the removable of the panel 6 for maintenance or replacement.

Referring to FIG. 3, the panels 6 may be raised in the upright position for stowage or relocation. A tubular member 30 has one end removably attached to an upper portion of an opposite side 14 and another end removably attached to the outer end 12 of the panel 6 to support the panel 6 in the upright position. The member 30 functions as a brace, supporting the panels 6 in the upright position during stowage or when moving to a different location. The member 30 is preferably plastic or lightweight metal. It should be understood that in the stowage position, each panel 6 is supported in the upright position by its respective tubular member 30.

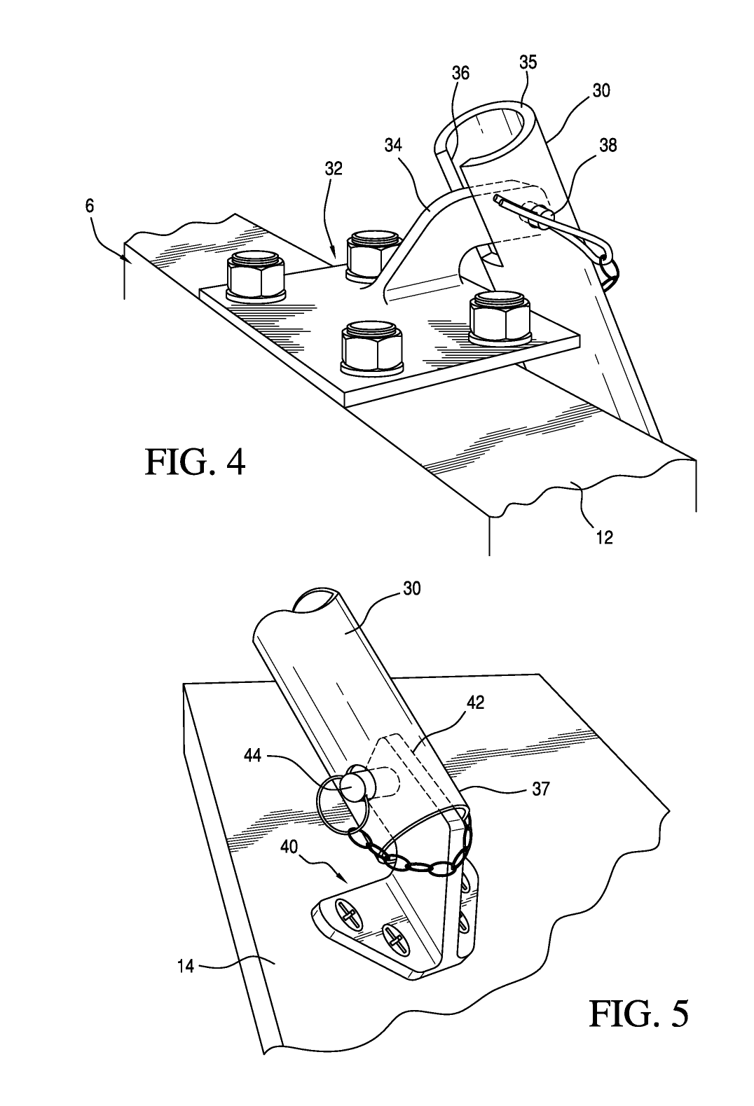

Referring to FIG. 4, a bracket 32 is attached to the outer end 12 of each panel 6. The bracket 32 includes a projecting member 34 that is received within the end portion 35 of the tubular member 30 through a slot 36. A removable pin 38 threaded through aligned holes in the wall of the tubular member 30 and the projecting member 34 secures the panel 6 to the tubular member 30. The opposite end portion 37 of the tubular member 30 is removably attached to the opposite side 14 with a bracket 40 including a projecting member 42 receivable within the tubular member 30. A removable pin 44 threaded through aligned holes in the wall of the tubular member 30 and the projecting member 42 secures the opposite end portion 37 of the tubular member 30 to the housing 4. Placing the end portion 37 of the tubular member 30 a further distance from the panel 6 by locating the end portion 37 at the opposite side of the housing 4 advantageously provides a more rigid stowage configuration. Each panel 6 is provided with the bracket 32 and each side 14 with the bracket 40.

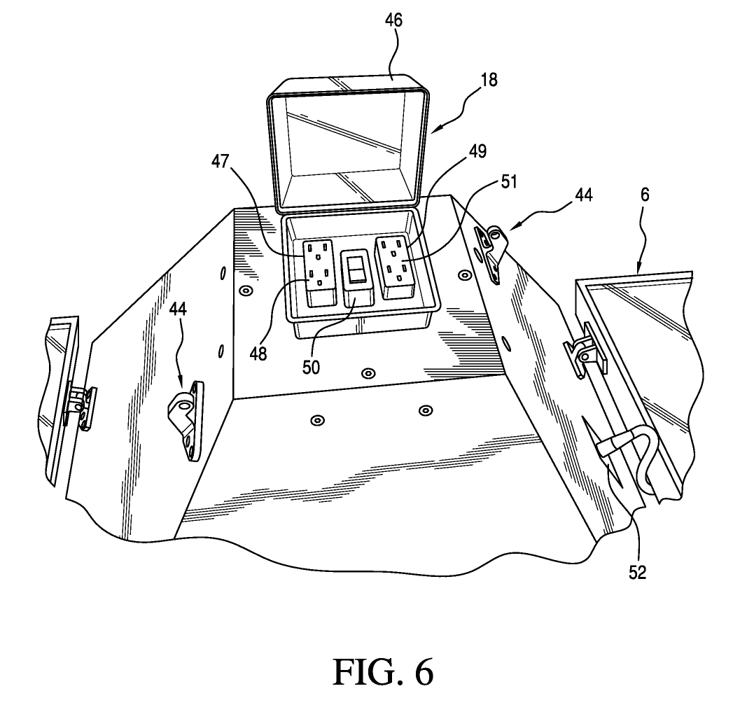

Referring to FIG. 6, the box 18 includes a cover 46 to provide access to power outlets 48, 47, 49 and 51 and a mode switch 50. The cover 46 protects the components from the weather. The outlet 48 is for connection to a house outlet for feeding the generated power to the house loads connected to the house outlet circuit and any excess to the electric grid through the house meter, thereby running the meter backwards for crediting to the customer's account with the utility company. A suitable cord would be used to connect the outlet 48 to an AC outlet in the house or building. Another outlet 47 is used for connecting another system 2 in daisy chain manner to increase the output of the system 2, if desired. Still another outlet 51 provides a DC output. Another outlet 49 is used for providing AC power when there the grid is down. A plug 52 removably connects each panel 6 to the electrical components inside the housing 4.

The solar power system 2 can be connected to the grid through an outlet in the house or building and automatically disconnects itself when the grid is down. The system 2 can also operate as an off-grid, stand-alone power generator in remote areas where grid power is unavailable.

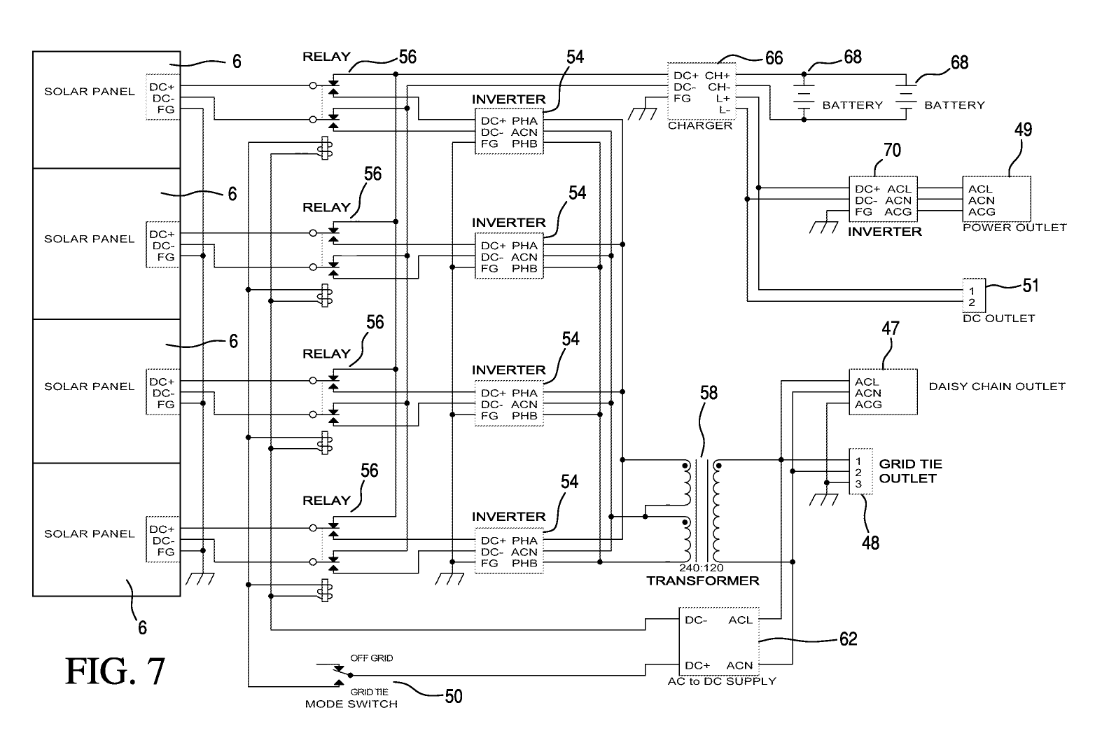

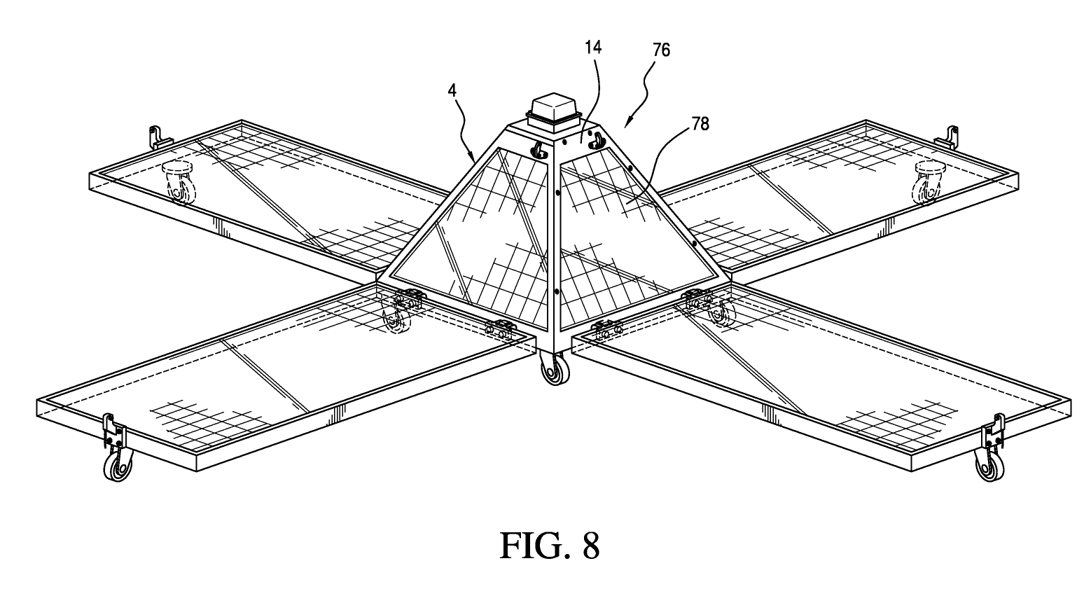

Referring to FIG. 7, each solar panel 6 is connected to a respective inverter 54 via a respective relay 56. Each inverter 54 converts the DC output of each panel 6 to 240 VAC. A transformer 58 lowers the voltage to 120 VAC for residential usage. The inverters 54 automatically sense the presence of the grid tie power signal and synchronize themselves to it. Power is then converted from the DC form obtained from the solar panels into the properly synchronized AC form for connection to the grid. The outlet 48 is used to connect the output of the transformer 58 to a residential power outlet, such as a wall outlet (not shown) to power the house loads connected to the outlet circuit. Any generated excess power is advantageously fed back into the electric grid through the house meter for crediting to the customer's account with the utility company.

The panels 6 available from Andalay Solar are each capable of producing up to 175 watts of DC power. The output voltage and current of the panels varies depending on the intensity of the incident solar radiation and the electrical load. The voltage typically ranges over a range of 25 to 39 volts. There is a point of maximum output power where the panels 6 should be operated in order to maximize their efficiency in converting solar energy to electrical energy. The inverters 54 are designed to operate the panels 6 at this maximum power point. The inverters 54 are commercially available, such as from Enphase Energy, 201 1st Street, Petaluma, Calif. 94952, www.enphaseenergy.com, Model No. M90-72-240-S11/2.

An AC to DC power supply 62 provides power to the relays 56 through the switch 50. The switch 50 has a grid tie position and an off tie position. When the switch 50 is in the grid tie position, power from the supply 62 will energize the relays 56 to connect the output of the panels 6 to the respective inverters 54, which in turn provide power to the connector 48, which is used to feed the generated power to the house loads through a standard wall outlet and to send any excess power to the electric grid through the house electric meter.

When the switch 50 is in the grid tie position, and if the power from the grid is ever lost, the inverters 54 will sense that condition and automatically shut-down their output to prevent “unintentional islanding,” a condition that happens when a utility grid is down, for maintenance as an example, and the distributed generation continues to feed the grid, which could have devastating consequences, as the power lines may still be energized without the knowledge of the utility, and consequently, the maintenance workers. When the outputs of the inverters 54 shut down, the input to the power supply 62 disappears, its output goes off and the relays 56 are no longer powered, thus causing them to reconnect the solar panel outputs to the charger 66 to charge the batteries 68. The energy from the solar panels 6 is thus always being captured either by the AC grid or the batteries 68. During the time that the electric grid is down, loads may be powered from the outlets 49 and 51.

When the switch 50 is in the off grid position, the relays 56 are de-energized to connect the output of the panels 6 to the battery charger 66, which is used to charge the batteries 68. Output from the batteries 68 is fed to an inverter 70 to provide an AC output through outlet 49. The output from the batteries 68 is also fed to the outlet 51 to provide a DC output. The DC power outlet 51 is similar to those found in automobiles for convenient connection of devices designed for use in that environment.

The battery charger 66 measures the amount of power going into the batteries 68 as well as the amount of power coming out of the batteries, thus allowing for the implementation of an indicator (not shown) showing the exact state of their charge. The charger 66 converts the high voltage from the solar panels 6 into the level required by the battery. The charger 66 constantly monitors the battery's state of charge and terminates charging when the battery becomes fully charged. The charger 66 monitors the current being extracted from the battery by the inverter 70 and the DC power outlet 51 Through this monitoring process, the charger 66 always knows the state of charge of the battery.

The inverter 70 differs from the inverters 54 in that it is not designed to be connected to the electric grid but to operate devices completely independent from it. The inverter 70 is commercially available, such as from Samlex America, 110-17 Fawcett Road, Coquitlam, BC, V3K 6V2 Canada, www.samlexamerica.com, Model No. PST-60s⁻¹²A.

It should be understood that the switch 50, the relays 56 and the power supply 65 constitute a switching circuit that provides the function of automatically switching the output of the panels 6 between the inverters 54 and the charger 66 depending on whether the electric grid is on or off. When the system 2 is connected to the electric grid through the outlet 48, and the switch 50 is in the grid tie position, the output of the panels 6 will be automatically disconnected from the inverters 54 and connected to the charger 66 when the electric grid goes down, thereby cutting off the power output to the grid. When power to the grid is restored, the output of the panels 6 is automatically switched to the inverters 54.

The switching circuit also provides the means for manually selectively switching the output of the panels 6 between the inverters 54 and the charger 66 through the mode switch 50. When the switch 50 is in the off grid position, the output of the panels 6 is always connected to the charger 66, regardless of whether there is power or not in the electric grid. Accordingly, when it is desired to operate the system 2 in the off grid mode, the switch 50 is opened to break the power to the relays 56, which causes the relays 56 to connect the panels 6 to the charger 66. When it is desired to operate the solar power system 2 in the grid tie mode, the switch 50 is closed to connect the power from the power supply 62 to the relays 56.

Referring back to FIG. 3, the various electrical components disposed within the housing 4 are visible after one side 14 has been temporarily removed. Some of the components shown are the inverters 54 and 66, the transformer 58 and the batteries 68.

The system 2 is designed to generate electricity from solar radiation and deliver it either to the AC power grid or use it to charge internal batteries that can then deliver power when solar radiation is not available, or when the electric grid is not available, such as in a remote area or when the grid is down for some reason.

Another embodiment of a solar power system 76 is disclosed in FIG. 8. The system 76 is the same as the system 2, except that the outer surfaces of the sides 14 of the housing 4 are covered with photovoltaic solar panels 78. The panels are operably connected together to increase the power output of the system 2.

The solar power system disclosed herein makes it possible for anyone to set up their own solar array capable of generating a daily minimum of about 4 kilowatt-hours of power for feeding back into the electric grid, thereby both running their electric meter backwards and “banking” electricity to be drawn on later or accomplishing a real time reduction of power usage from the grid. In addition, this onsite mini-power generation package would reduce the user's carbon footprint, lower the instances of blackouts and brownouts by adding generating capacity to the grid at peak usage periods. The device would further serve as an instant power source on locations throughout the world both for recreation and emergency use. The system 2 could be in storage and be immediately available for emergency.

The solar power system of the present invention could become a worldwide network of power generation as the use of plug-in electric vehicles become more popular and widespread. Tied to the electric grid, the system 2 could provide power at varied locations such as at fast food restaurants, hotels, rest stops and many other places along the highways. The solar power gathering function would add generating capacity to the grid.

The system 2 has several advantageous over an engine-generator. The system 2 advantageously generates clean, regulated power output. It has very long, efficient, run times at low power usage. It is completely quiet. It can be used indoors when fully charged and rolled outside to be charged.

While this invention has been described as having preferred design, it is understood that it is capable of further modification, uses and/or adaptations following in general the principle of the invention and including such departures from the present disclosure as come within known or customary practice in the art to which the invention pertains, and as may be applied to the essential features set forth, and fall within the scope of the invention or the limits of the appended claims.

I claim:

1. A portable solar power system, comprising:
a) a plurality of photovoltaic solar panels;
b) storage batteries for storing energy generated by said photovoltaic solar panels;
c) a charger operably connected to said photovoltaic solar panels for charging said storage batteries;
d) a plurality of inverters operably connected to respective said photovoltaic solar panels for generating an AC output for connection to an outlet for feeding into an electric grid; and
e) a switching circuit for automatically disconnecting said photovoltaic solar panels from said inverters and connecting said photovoltaic solar panels to said charger when power in the electric grid is down.

2. A portable solar power system as in claim 1, and further comprising:
a) a housing having a plurality of sides; and
b) said panels include a deployed position and a stowage position, said panels are substantially horizontal when in said deployed position for being exposed to solar radiation, said panels are being upright when in said stowage position.

3. A portable solar power system as in claim 2, wherein:
a) said sides each includes a bottom portion; and
b) said photovoltaic solar panels are attached to respective said bottom portion.

4. A portable solar power system as in claim 2, and further comprising a plurality of hinges for attaching said photovoltaic solar panels to said sides.

5. A portable solar power system as in claim 4, wherein said hinges each includes a removable pin for detaching said photovoltaic solar panels from said sides.

6. A portable solar power system as in claim 2, wherein said housing is pyramidal.

7. A portable solar power system as in claim 2, and further comprising:
a) a plurality of tubular members;
b) one end of each tubular member is removably attached to a respective one of said sides; and
c) an opposite end of each tubular member is removably attached to a respective free end of one of said photovoltaic solar panels.

8. A portable solar power system as in claim 7, wherein:
a) each of said sides and each of said free ends include a bracket with a protruding portion; and
b) said protruding member is receivable within respective said one end and respective opposite end within respective one end and respective opposite end of each of said tubular members.

9. A portable solar power system as in claim 8, wherein:
a) each of said protruding members includes an opening;
b) each end and each another end of said tubular members include a transverse opening alignable with said opening of said protruding member; and
c) a removable pin disposed through said transverse opening at each end and each another end of said tubular members, and through said opening of respective said protruding member.

10. A portable solar power system as in claim 2, and further comprising another plurality of photovoltaic solar panels laid on top of said sides.

11. A portable solar power system as in claim 1, wherein:
a) said switching circuit includes relays operably connected to said photovoltaic solar panels and said inverters; and
b) a switch operably connected to said relays and a power source.

12. A portable solar power system as in claim 11, wherein:
a) said switch includes a grid tie position and an off grid position;
b) said grid tie position connects said relays to the power source; and
c) said off grid position disconnects said relays from the power source.

13. A portable solar power system as in claim 1, and further comprising a transformer operably connected to said inverters.

14. A portable solar power system as in claim 1, and further comprising another inverter operably connected to said batteries.

15. A portable solar power system, comprising:
a) a housing having a plurality of sides;
b) a plurality of photovoltaic solar panels hingedly attached to respective said sides;
c) said panels including a deployed position and a stowage position, said panels are substantially horizontal when in said deployed position for being exposed to solar radiation, said panels are being upright when in said stowage position; and
d) a plurality of inverters operably connected to respective said photovoltaic solar panels for generating an AC output for connection to an outlet for feeding into an electric grid.

16. A portable solar power system as in claim 15, wherein:
a) said sides each includes a bottom portion; and
b) said photovoltaic solar panels are attached to respective said bottom portion.

17. A portable solar power system as in claim 16, wherein said housing is pyramidal.

18. A portable solar power system as in claim 17, and further comprising another plurality of photovoltaic solar panels laid on top of said sides.

19. A portable solar power system as in claim 15, and further comprising a plurality of wheels disposed underneath said housing.

20. A portable solar power system as in claim 15, wherein said photovoltaic solar panels are detachable from said housing.
